(19) United States
(12) Patent Application Publication
(10) Pub. No.: US 2006/0170105 A1
(43) Pub. Date: Aug. 3, 2006

(54) Semiconductor device featuring probe area definition mark for defining probe area in electrode pad, and proof test system for proving proper contact of test probe with probe area

(75) Inventor: Miho Hirai, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/340,695

(22) Filed: Jan. 27, 2006

(30) Foreign Application Priority Data
Jan. 28, 2005 (JP) 2005-020473

(51) Int. Cl. H01L 23/52

(52) U.S. Cl. 257/758

(57) ABSTRACT

In a semiconductor device including a semiconductor substrate, a multi-layered wiring structure is formed on the semiconductor substrate, and an electrode pad is formed on the multi-layered wiring structure. There is a probe area definition mark element that defines a probe area in the electrode pad, with which a test probe be contacted, and the probe area definition mark element is provided at a location spaced away from the electrode pad.

### BACKGROUND OF THE INVENTION

1. Field of the Invention

The present invention relates to a semiconductor device having a plurality of electrode pads with which a test probe is not only contacted, and on which a bonding wire is bonded, and also relates to a proof test system for proving whether or not the contact of a test probe with an electrode pad is properly carried out.

2. Description of the Related Art

In a representative process of manufacturing a plurality of semiconductor devices, a semiconductor wafer, such as a silicon wafer, is prepared, and a surface of the semiconductor wafer is sectioned into a plurality of semiconductor chip areas which are defined by grid-like scribe line areas, and a semiconductor device is manufactured in each of the chip areas. Namely, the semiconductor chip area or device includes a rectangular internal circuit area section in which various internal circuits, such as memory circuits, logic circuits and so on, are produced, and a plurality of input/output (I/O) area sections arranged along the sides of the rectangular internal circuit area section, with an I/O buffer being formed in each of the I/O area sections.

Then, a multi-layered wiring structure, including insulating interlayers and wiring pattern layers which are alternately stacked with each other, is formed on the semiconductor substrate, and a plurality of electrode pads are formed on the uppermost insulating interlayer of the multi-layered wiring structure for the I/O buffers.

Thereafter, the semiconductor devices are subjected to a test in which it is examined whether or not each of the semiconductor devices is properly operated, using a test apparatus having a plurality of test probes. In the test, the test probes are contacted with the respective electrode pads of the semiconductor device on the semiconductor wafer, and test voltages are applied to test probes to examine whether or not each of the semiconductor devices is properly operated. In order to ensure the application of the test voltage to the electrode pads, the test probes are pressed against the respective electrode pads with a suitable pressure. Nevertheless, the pressure may cause cracks in a local area of an insulating interlayer which is immediately beneath each of the electrode pads.

Accordingly, the wiring pattern layer is excluded from the local area on the insulating interlayer immediately beneath the electrode pad. Thus, the freedom of a wiring layout design for the I/O buffer concerned is considerably restricted.

Also, during the execution of the test, the surface of the electrode pad is marked with a plurality of scores because the test is repeated several times with respect to the semiconductor devices. In particular, whenever the test is repeated, each of the test probes is contacted with and pressed against the corresponding electrode pad, resulting in the marking of the surface of the electrode pad with scores.

After the test is completed, the semiconductor wafer is subjected to a dicing process in which the semiconductor wafer is cut along the grid-like scribe line areas, so that the semiconductor chip areas or devices are separated from each other. The semiconductor devices which have not passed the test are discarded while the semiconductor devices which have passed the test are used for forming semiconductor packages.

In the formation of the semiconductor packages, a wire is bonded on the electrode pad by using, for example, an ultrasonic-pressure type wire-bonding apparatus. In this s case, the scores hinder good bonding between the bonded wire and the electrode pad. Namely, a contact area between the end of the bonded wire and the electrode pad is considerably reduced due to the existence of the scores and, thus, it is impossible to ensure a sufficient bonding strength therebetween. Note, although a tape-like lead may be substituted for the bonding wire, the same is true for the tape-like lead.

In another prior art semiconductor device (see: JP-2002-320742-A), a plurality of test pads and a plurality of bonding pads are provided in each of I/O area sections of a semiconductor chip area or device, so that each of the test pads integrally extends from the corresponding one of the bonding pads. Namely, the test pads are used only for the test of the semiconductor device, and the bonding pads are used only for the bonding of bonding wires. Thus, as the surface of the bonding pad cannot be marked with scores, it is possible to ensure a sufficient bonding strength between the end of the bonded wire and the bonding pad.

However, this prior art semiconductor device is contrary to a trend toward the miniaturization and integration of semiconductor devices, because an occupation area is required for both the test pad and the bonding pad.

### SUMMARY OF THE INVENTION

Therefore, an object of the present invention is to provide a semiconductor device having a plurality of electrode pads and featuring a probe area definition mark element for defining a probe area, in each of the electrode pads, with which a test probe should be contacted.

Another object of the present invention is to provide a proof test system for proving whether or not a test probe is properly contacted with such a probe area defined in the electrode pad.

In accordance with a first aspect of the present invention, there is provided a semiconductor device which includes a semiconductor substrate, a multi-layered wiring structure formed on the semiconductor substrate, an electrode pad formed on the multi-layered wiring structure, and a probe area definition mark element for defining a probe area in the electrode pad, with which a test probe should be contacted.

Preferably, the probe area definition mark element is provided at a location spaced away from the electrode pad.

In the semiconductor device, for the formation of the electrode pad, preferably, a metal layer is formed on an uppermost insulating interlayer of the multi-layered wiring structure, and an insulating layer or passivation layer is formed on the metal layer. Then, an opening is perforated in the insulating layer so that a part of the metal layer is exposed to the exterior as the electrode pad. In this case, preferably, the location, at which the probe area definition mark element is provided, is spaced away from a peripheral edge of the opening.

The probe area definition mark element may be located in a scribe line area defined on the semiconductor substrate. Optionally, the probe area definition mark element may be located at a margin area of a semiconductor chip area which is defined on the semiconductor substrate, and at which the semiconductor device is produced.

The probe area definition mark element may be defined as an impurity diffusion region formed in the semiconductor substrate. Optionally, the probe area definition mark element may be defined as a metal layer formed on an insulating interlayer of the multi-layered wiring structure.

The semiconductor device may be further provided with a bonding area definition mark element which collaborates with the bonding area definition mark element to define a bonding area, on the electrode pad, on which a bonding wire should be bonded.

In the semiconductor device, a wiring pattern layer can be formed on an insulating interlayer of the multi-layered wiring structure which is immediately beneath the electrode pad, but the formation of the wiring pattern layer is excluded from a local area on the insulating interlayer which is immediately beneath the probe area of the electrode pad.

In accordance with a second aspect of the present invention, there is provided a semiconductor device which includes a semiconductor substrate, a multi-layered wiring structure formed on the semiconductor substrate, a plurality of electrode pads formed on the multi-layered wiring structure so as to be aligned with each other, and a first probe area definition mark element and a second probe area definition mark element which are arranged so that said electrode pads are aligned and intervened there between to define respective probe areas, in said electrode pads, with which test probes should be contacted.

In accordance with a third aspect of the present invention, there is provided a proof test system for proving whether a test probe is properly contacted with a probe area defined in an electrode pad on a semiconductor device featuring a probe area definition mark element. The proof test system includes an image sensor for photographing the electrode pad with together the probe area definition mark element, and a line generator system for generating a geometrical line based on the photographed image of the probe area definition mark element, to thereby define the probe area in the electrode pad, the remaining area of the electrode pad being defined as a bonding area to which a bonding wire should be bonded. The proof test system further includes an image processing system for processing image data representing the bonding area of the electrode pad, and a determination system for determining whether or not the bonding area is marked with a score by the test probe based on the image data processed by the image processing system,

The proof test system may further include a data storage system for storing reject data, indicating that the semiconductor device concerned should be rejected, when the marking of the bonding area with the score is confirmed by the determination system.

The proof test system may also include a display system that displays the image photographed by the image sensor, and the geometrical line generated by the line generator system.

### BRIEF DESCRIPTION OF THE DRAWINGS

The above objects and other objects will be more clearly understood from the description set forth below, with reference to the accompanying drawings, wherein:

FIG. 1 is a partial plan view of a semiconductor wafer including a plurality of prior art semiconductor devices;

FIG. 2 is a partially-enlarged view of FIG. 1, showing one of the semiconductor devices;

FIG. 3 is a cross-sectional view taken along the line 111-Ill of FIG. 2;

FIG. 4 is a plan view of the I/O area section of FIG. 3;

FIG. 5 is a partial plan view of a semiconductor wafer including a plurality of semiconductor devices according to a first embodiment the present invention;

FIG. 6 is a partially-enlarged view of FIG. 5, showing one of the semiconductor devices;

s FIG. 7 is a cross-sectional view taken along the line VII-VII of FIG. 6;

FIG. 8 is a partial plan view of the consecutive two semiconductor devices which are arranged along the X-coordinate axis of the X-Y coordinate system of FIG. 5;

FIG. 9 is a partial plan view of the consecutive three semiconductor devices which are arranged along the Y-coordinate axis of the X-Y coordinate system of FIG. 5;

FIG. 10 is a block diagram of the test system for carrying out a test of the semiconductor devices on the semiconductor wafer of FIG. 5;

FIG. 11 is a flowchart of the test routine which is executed in the system control unit of the test system of FIG. 10;

FIG. 12 is a plan view of an input/output (I/O) area section on the semiconductor device for assisting the explanation of the flowchart of FIG. 11;

FIGS. 13A and 13B are plan views of the I/O area section on the semiconductor devices tested by the test system of FIG. 10;

FIG. 14 is a flowchart of the proof routine which is executed in the system control unit of the test system of FIG. 10;

FIGS. 15A and 15B are plan views of the I/O area section on the semiconductor devices tested by the test system of FIG. 10, for explaining a wire bonding process;

FIG. 16 is a cross-sectional view illustrating a second embodiment of the semiconductor device according to the present invention;

FIG. 17A is a partial plan view illustrating a third embodiment of the semiconductor device according to the present invention;

FIG. 17B is a partial plan view illustrating a modification of the third embodiment of FIG. 17A;

FIG. 18 is a partial plan view illustrating a fourth embodiment of the semiconductor device according to the present invention;

FIG. 19A is a partial plan view illustrating a fifth embodiment of the semiconductor device according to the present invention;

FIG. 19B is a partial plan view illustrating a modification of the third embodiment of FIG. 19A;

FIG. 20A is a partial plan view illustrating a sixth embodiment of the semiconductor device according to the present invention;

FIG. 20B is a partial plan view illustrating a modification of the sixth embodiment of FIG. 20A; and

FIG. 21 is a partial plan view illustrating a seventh embodiment of the semiconductor device according to the present invention.

### DESCRIPTION OF THE PREFERRED EMBODIMENTS

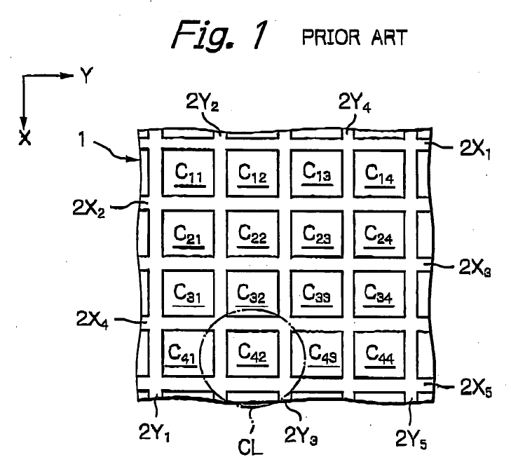

Before the description of the preferred embodiments of the present invention, for a better understanding of the present invention, a prior art semiconductor device will be now explained with reference to FIGS. 1 to 4.

First, in FIG. 1, a semiconductor wafer 1, such as a silicon wafer, is partially illustrated in a plan view. A plurality of rectangular semiconductor chip areas Cᵢⱼ (1≦i≦4 and 1≦j≦4) are defined on a surface of the semiconductor wafer 1 by grid-like scribe line areas 2X₁ to 2X₅ and 2Y₁ to 2Y₅, and one semiconductor device is produced in each of the semiconductor chip areas Cᵢⱼ.

Note, in FIG. 1, an X-Y coordinate system is defined with respect to the semiconductor wafer 1, the scribe line areas 2X₁ to 2X₅ extend along the Y-coordinate axis of the X-Y coordinate system, and the scribe line areas 2Y1 to ZY₅ extend along the X-axis coordinate axis of the X-Y coordinate system.

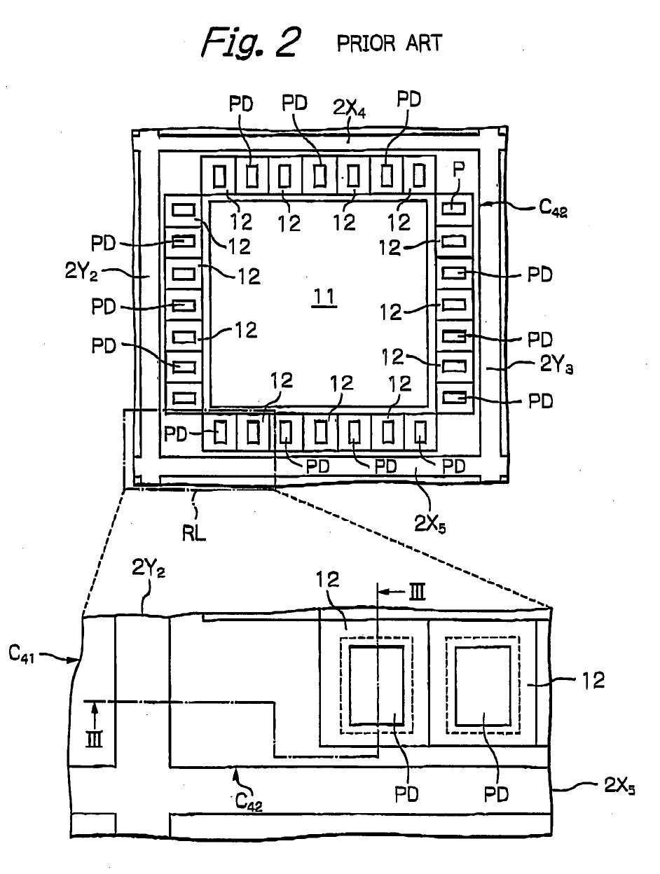

Referring to FIG. 2, which is a partially-enlarged plan view of FIG. 1, and which shows the semiconductor chip area C₄₂ encircled by a circular chain-dot line CL. in FIG. 1, the semiconductor chip area or device C₄₂ includes a rectangular internal circuit area section 11 in which various internal circuits (not shown), such as memory circuits, logic circuits and so on, are formed, and a plurality of input/output (I/O) area sections 12 arranged along the peripheral sides of the rectangular internal circuit area section 11. Each of the I/O area sections 12 is provided with one electrode pad PD which is made of a suitable metal material, for example, aluminum, and the electrode pads PD are aligned with each other along each of the peripheral sides of the internal circuit area section 11. In FIG. 2, note that a part of the semiconductor device C₄₂, which is encircled by a rectangular chain-dot line RL, is illustrated in an enlarged scale.

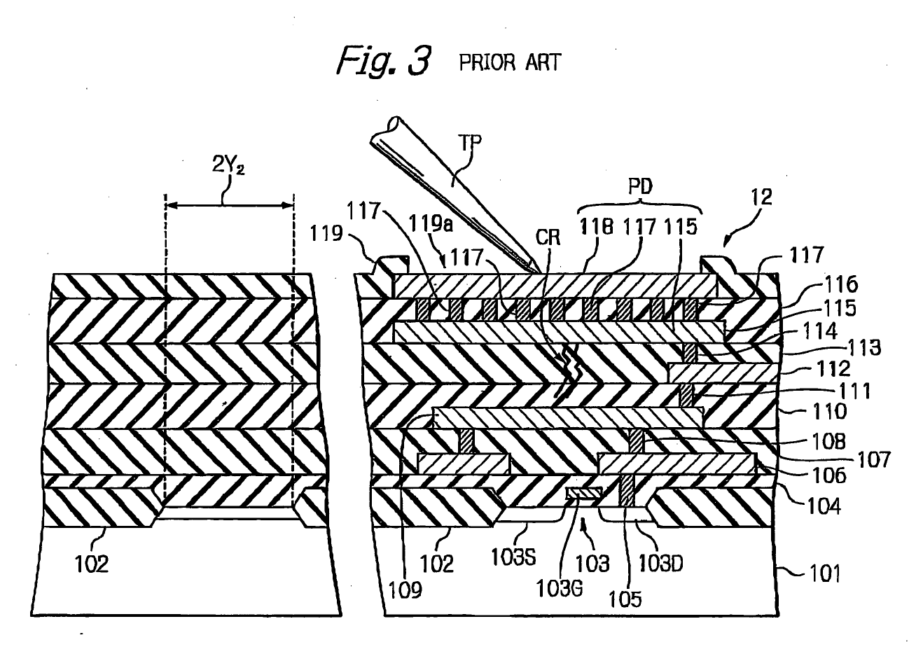

As shown in FIG. 3 which is a cross-sectional view taken along the line III-III of FIG. 2, the semiconductor chip area or device C₄₂ includes a semiconductor substrate 101, and an element-isolation layer 102 formed on the semiconductor substrate 101. The semiconductor device chip area or device C₄₂ is defined by an outer contour of the element-isolation layer 102, and the scribe line area 2Y₂ is defined as an area between the consecutive two element-isolation layers 102 arranged along the Y-coordinate axis (see: FIG. 1). Note, although not visible in FIG. 3, the scribe line area 2X₅ is defined as an area between the consecutive two element-isolation layers 102 arranged along the X-coordinate axis (see: FIG. 1).

Also, as representatively shown in FIG. 3, each of the I/O area sections 12 is defined in the element-isolation layer 102 concerned, and an I/O buffer is formed at the I/O area section 12 in the semiconductor substrate 101. The I/O buffer includes at least one metal oxide semiconductor (MOS) transistor 103 having an impurity-diffusion region or source region 103S, an impurity-diffusion region or drain region 103D, and a gate electrode 103G.

In order to form the source region 103S and the drain region 103D, an impurity implanting process is usually carried out. In this case, the scribe line areas 2X₁ to 2X₅ and 2Y₁ to 2Y₅ are not masked, and thus each of the scribe line areas 2X₁ to 2X₅ and 2Y₁ to 2Y₅ is defined by the same impurity-diffusion region as the source region 103S and the drain region 103D.

Note, although not illustrated in FIG. 3, various semiconductor elements, such as transistors, resistors, capacitors and so on, are formed in the semiconductor substrate 101.

After the semiconductor elements are formed in the semiconductor substrate 101, a multi-layered wiring structure is formed on the semiconductor substrate 101, as shown in FIG. 3.

In particular, an insulating interlayer 104 is formed on the semiconductor substrate 101 so as to cover the element-isolation layers 102, and a via plug 105 is formed in the insulating interlayer 104 so as to be connected to the I/O buffer, such as the drain region 103D of the NOS transistor 103. A wiring pattern layer 106 is formed on the insulating interlayer 104, and is connected by the via plug 105 to the I/O buffer.

Then, an insulating interlayer 107 is formed on the insulating interlayer 104 so as to cover the wiring pattern layer 106, and a via plug 108 is formed in the insulating interlayer 107. A wiring pattern layer 109 is formed on the insulating interlayer 107, and is connected by the via plug 108 to the wiring pattern layer 106.

Next, an insulating interlayer 110 is formed on the insulating interlayer 107 so as to cover the wiring pattern layer 109, and a via plug 111 is formed in the insulating interlayer 110. A wiring pattern layer 112 is formed on the insulating interlayer 110, and is connected by the via plug 111 to the wiring pattern layer 109.

Next, an insulating interlayer 113 is formed on the insulating interlayer 110 so as to cover the wiring pattern is layer 112, and a via plug 114 is formed in the insulating interlayer 113. A metal layer 115 is formed on the insulating interlayer 113, and is connected by the via plug 114 to the wiring pattern layer 112.

Further, an insulating interlayer 116 is formed on the insulating interlayer 113 so as to cover the metal layer 115, and a plurality of via plugs 117 are formed in the insulating interlayer 116. A metal layer 118 is formed on the insulating interlayer 116, and is connected by the via plug 117 to the metal layer 115.

Note, the metal layers 115 and 118 and the via plugs 117 form a circuit under pad (CUP) double-structured pad PD (see: FIG. 2) for the I/O buffer concerned.

The insulating interlayer 116 is covered with an insulating layer or passivation layer 119, and an opening 119a 30 is perforated therein so that a major part of the metal layer 118 is exposed to the exterior as the electrode pad PD.

Note, the wiring pattern layers 106, 109 and 112, the metal layers 115 and 118, and the via plugs 106, 108, 114 and 117 may be composed of a suitable metal material, such as aluminum or the like.

The semiconductor wafer 1, having the semiconductor chip areas or devices Cᵢⱼ, is subjected to a test in which it is examined whether or not each of the semiconductor devices Cᵢⱼ is properly operated, using a test apparatus having a plurality of test probes.

As representatively shown in FIG. 3, in the test, the test probes, indicated by reference TP, are contacted with the respective electrode pads PD of some of the semiconductor devices Cᵢⱼ on the semiconductor wafer 1, and test voltages are applied to the test probes TP to examine whether or not each of the semiconductor devices Cᵢⱼ is properly operated.

In order to ensure the application of the test voltage to the is electrode pads PD, the test probes TP are pressed against the respective electrode pads PD with a suitable pressure.

Nevertheless, the pressure may cause cracks CR in a local area of both the insulating interlayers 113 and 110, which are immediately beneath the CUP double-structured pad PD (115, 117, 118).

Accordingly, as shown in FIG. 3, the wiring pattern layer 112 is excluded from the local area on the insulating interlayer 110, which is immediately beneath the CUP double-structured pad PD (115, 117, 118). Thus, a freedom of the wiring layout design for the I/O buffer concerned is considerably restricted.

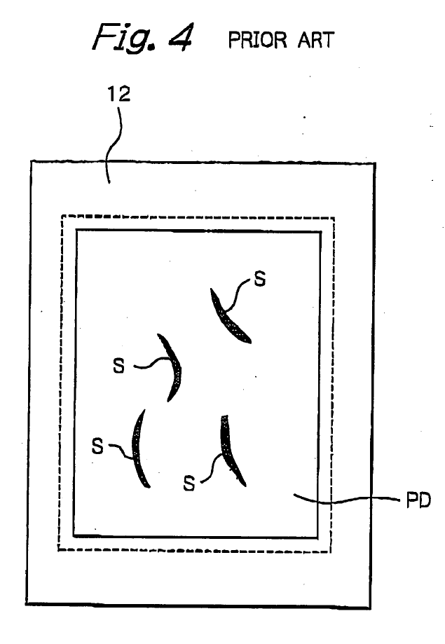

Also, as shown in FIG. 4 which is a plan view of FIG. 3, during the execution of the test, the surface of the electrode pad PD is marked with a plurality of scores S because the test is repeated several times with respect to the semiconductor devices Cᵢⱼ. In particular, whenever the test is repeated, each of the test probes TP is contacted with and pressed against the corresponding electrode pad PD, resulting in the marking of the surface of the electrode pad PD with the scores S.

After the test is completed, the semiconductor wafer 1 is subjected to a dicing process in which the semiconductor wafer 1 is cut along the grid-like scribe line areas 2X₁ to 2X₅ and 2Y₁ to 2Y₅, so that the semiconductor chip areas or devices are separated from each other. The semiconductor devices Cᵢⱼ which have not passed the test are discarded, while the semiconductor devices Cᵢⱼ which have passed the test are used for production of semiconductor packages.

In the production of the semiconductor packages, a wire is bonded on the electrode pad PD by using, for example, an ultrasonic-pressure type wire-bonding apparatus. In this case, the scores S hinder good bonding between the bonded wire and the electrode pad PD. Namely, a contact area between the end of the bonded wire and the electrode pad PD is considerably reduced due to the existence of the scores S, and thus it is impossible to obtain a sufficient bonding strength therebetween. Note, although a tape-like lead may be substituted for the bonding wire, the same is true for the tape-like lead.

### First Embodiment

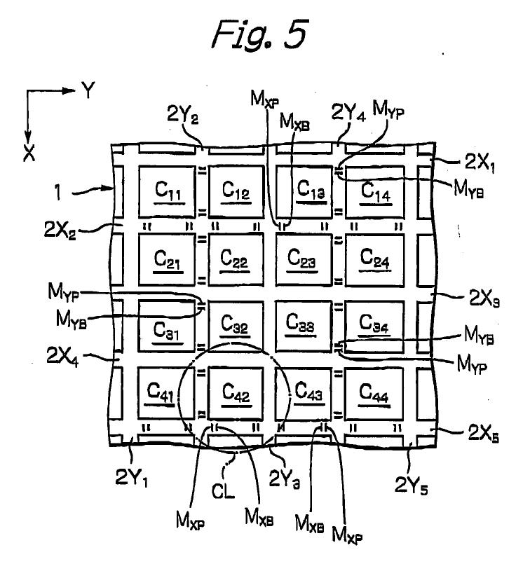

With reference to FIGS. 5 to 7, corresponding to FIGS. 1 to 3, respectively, a first embodiment of the semiconductor device according to the present invention is explained below.

In FIG. 5, the semiconductor wafer 1 is substantially the same as that of FIG. 1, except that each of the scribe line areas 2X₂ and 2X₅ features plural pairs of mark elements M_{XP} and M_{XB} formed therein, and that each of the scribe line areas 2Y₂ and ZY₄ features plural pairs of mark elements M_{YP} and M_{YB} formed therein. Note, functions of the mark elements M_{XP}, M_{XB}, M_{YP} and M_{YB} are stated in detail hereinafter.

The consecutive three semiconductor chip areas or devices (Cᵢⱼ), which are arranged between the scribe line areas 2X₂ and 2X₅ along the X-coordinate axis, are associated with four pairs of mark elements M_{XP} and M_{XB}. For example, in the consecutive three semiconductor devices C₂₂, C₃₂ and C₄₂, the semiconductor device C₂₂ is associated with the corresponding two pairs of mark elements M_{XP} and M_{XB} provided in the scribe line area 2X₂, and the semiconductor device C₄₂ is associated with the corresponding two pairs of mark elements M_{XP} and M_{XB} provided in the scribe line area 2X₅,

Also, the consecutive two semiconductor chip areas or devices (Cᵢⱼ), which are arranged between the scribe line areas ZY₂ and 2Y₄ along the Y-coordinate axis, are associated with four pairs of mark elements M_{YP} and M_{YB}. For example, is in the consecutive two semiconductor devices C₄₂ and C₄₃, the semiconductor device C₄₂ is associated with the corresponding two pairs of mark elements M_{YP} and M_{YB} provided in the scribe line area 2Y₂, and the semiconductor device C₄₃ is associated with the corresponding two pairs of mark elements M_{YP} and M_{YB} provided in the scribe line area 2Y₄.

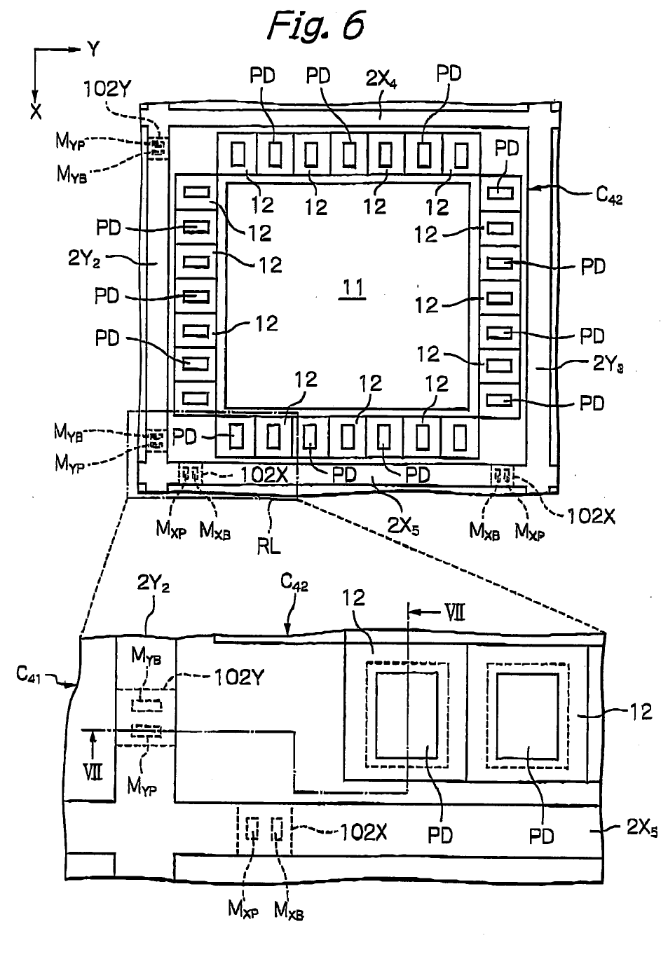

In FIG. 6, similar to FIG. 2, the semiconductor chip area C₄₂, which is encircled by a circular chain-dot line CL in FIG. 5, includes the rectangular internal circuit area section 11, and the plurality of input/output (I/O) area sections 12 arranged along the sides of the rectangular internal circuit area section 11, with each of the I/O area sections 12 being provided with the electrode pads PD which are made of a suitable metal material, for example, aluminum. Also, similar to FIG. 2, a part of the semiconductor device C₄₂, which is encircled by a rectangular chain-dot line. RL, is illustrated in an enlarged scale.

As shown in FIG. 7 which is a cross-sectional view taken along the line VII-VII of FIG. 6, an internal structure of the I/O area section 12 is substantially identical to that of FIG. 3, except that a wiring pattern layer 112′ partially extends and intrudes into the local area of the insulating interlayer 110, which is immediately beneath the CUP double-structured pad PD (115, 117, 118), with the wiring pattern layer 112′ being connected to the wiring pattern layer 109 through a via plug 111′ formed in the insulating interlayer 110.

As discussed with reference to FIG. 3, in the prior art, the formation of the wiring pattern layer 112 is excluded from the local area of the insulating interlayer 110, which is immediately beneath the CUP double-structured pad PD (115, 117, 118). However, in FIG. 7, the partial extension and intrusion of the wiring pattern layer 112′ into the aforesaid local area of the insulating interlayer 110 is allowed for the reasons stated in detail hereinafter.

Also, as shown in FIGS. 6 and 7, for the formation of the pairs of mark elements M_{YP} and M_{YB} provided in the scribe line area 2Y₂, the consecutive two element-isolation layers 102, which are arranged along the Y-coordinate axis, are connected to each other by sections 102Y which are integrally extended therebetween, and a pair of rectangular openings are perforated in each of the sections 102Y so that each of the mark elements M_{YP} and M_{YB} is defined as an impurity-diffusion region. The same is true for the other pairs of mark elements M_{YP} and M_{YB}.

Note, in FIG. 7, only the mark element (impurity-diffusion region) M_{YP} is visible. Also, note, as the insulating interlayers 104, 107, 110, 113 and 117 and the passivation layer 121 are so thin that they are semi-transparent, the mark elements M_{YP} and M_{YB} can be observed and recognized through these semi-transparent layers 104, 107, 110, 113, 117 and 121.

Similarly, as shown in FIG. 6, for the formation of the pairs of mark elements M_{XP} and M_{XB} provided in the scribe line area 2X₁, the consecutive two element-isolation layers 102, which are arranged along the X-coordinate axis, are connected to each other by sections 102X which are integrally extended therebetween, and a pair of rectangular openings are perforated in each of the sections 102X so that each of the mark elements M_{XP} and M_{XB} is defined as an impurity-diffusion region, with the mark elements M_{XP} and M_{XB} being observed and recognized through the semi-transparent layers 104, 107, 110, 113, 117 and 121. The same is true for the other pairs of mark elements M_{XP} and M_{XB}.

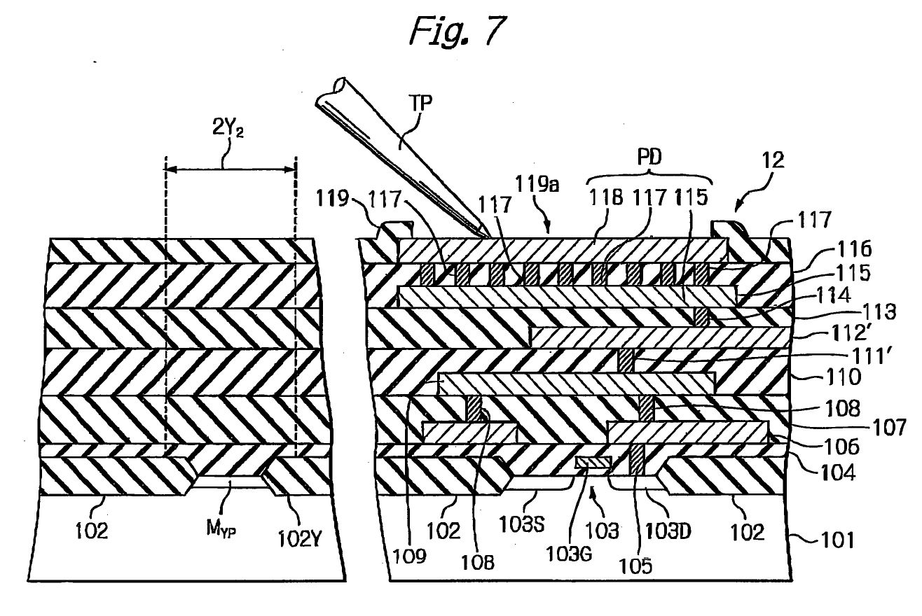

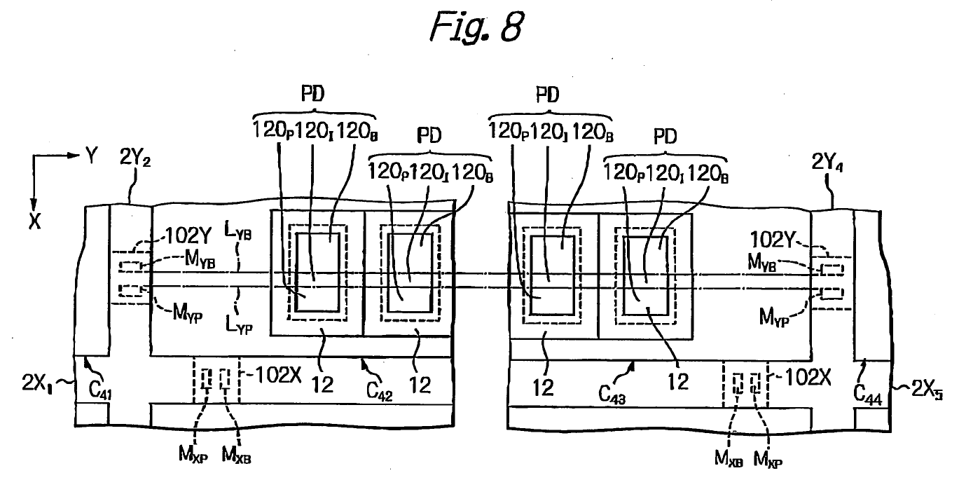

In FIG. 8, the consecutive two semiconductor chip areas or devices C₄₂ and C₄₃, which are arranged along the Y-coordinate axis, are illustrated. The consecutive two mark elements M_{YP}, provided in the respective scribe line areas 2Y₂ and 2Y₄, are opposed to each other, with the semiconductor devices C₄₂ and C₄₃ being intervened between the consecutive two mark elements M_{YP}. The two mark elements M_{YP} are used to generate a geometrical line L_{YP} extending therebetween, so that probe areas 120_{P} are defined in the respective electrode pads PD arranged along the scribe line area 2X₅.

Similarly, the consecutive two mark elements M_{YB}, provided in the respective scribe line areas 2Y₂ and 2Y₄ and opposed to each other, are used to generate a geometrical line L_{YB} extending therebetween, so that bonding areas 120_{P} are defined in the respective electrode pads PD arranged along the scribe line area 2X₅, with an intermediate area 102_{I} being defined, between the probe area 120_{P} and the bonding area 120_{B}, at each of the electrode pads PD.

In short, the mark elements M_{YP} serve as probe area definition mark elements for defining the probe areas 120_{P} in the respective electrode pads PD arranged along the scribe line area 2X₅, and the mark elements M_{YB} serve as bonding area definition mark elements for defining the bonding areas 120_{B} in the electrode pads PD arranged along the scribe line area 2X₅.

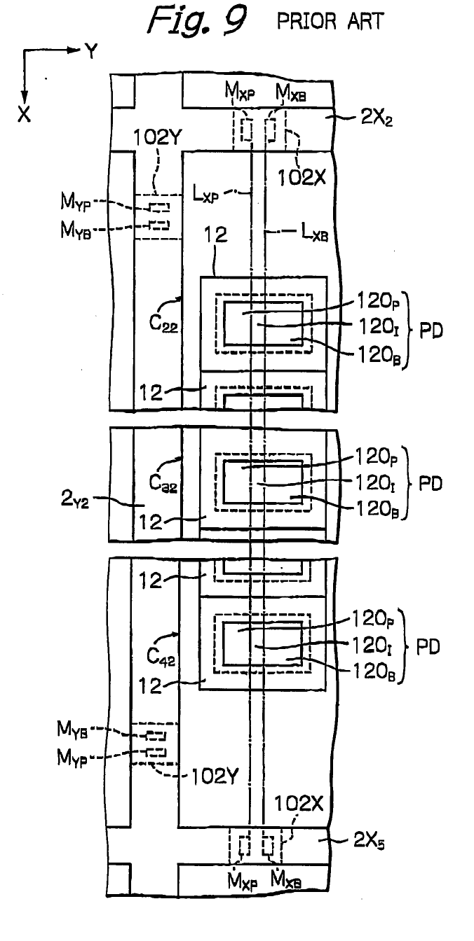

In FIG. 9, the consecutive three semiconductor chip areas or devices C₂₂, C₃₂ and C₄₂, which are arranged along the X-coordinate axis, are illustrated. The consecutive two mark elements M_{XP}, provided in the respective scribe line areas 2X₂ and 2X₅, are opposed to each other, with the semiconductor devices C₂₂, C₃₂ and C₂₄ being intervened between the consecutive two mark elements M_{XP}. The two mark elements M_{XP} are used to generate a geometrical line L_{XP} extending therebetween, so that probe areas 120_{P} are defined in the respective electrode pads PD arranged along the scribe line area 2Y₂.

Similarly, the consecutive three mark elements M_{XB}, provided in the respective scribe line areas 2X₂ and 2X₅ and opposed to each other, are used to generate a geometrical line L_{XB} extending therebetween, so that bonding areas 120_{B} are defined in the respective electrode pads PD arranged along the scribe line area 2Y₂, with an intermediate area 102_{I} being defined between the probe area 120_{P} and the bonding area 120_{B} at each of the electrode pads PD.

In short, the mark elements M_{XP} serve as probe area definition mark elements for defining the probe areas 120_{P} in the electrode pads PD arranged along the scribe line area 2Y₂, and the mark elements M_{XB} serve as bonding area definition mark elements for defining the bonding areas 120_{B} in the electrode pads PD arranged along the scribe line area 2Y₂.

Returning to FIG. 7, the test probe TP is contacted with and pressed against the probe area 120_{P} on the electrode pad PD when the test is carried out. Namely, the probe area 120_{P} is defined as an area against which the test probe TP should be contacted and pressed. On the other hand, the bonding area 120_{B} is defined as an area on which a wire is bonded.

Accordingly, the wiring pattern layer 112′ can partially extend and intrude into a local area of the insulating interlayer 110, which is immediately beneath the bonding area 120_{B}, because no crack is caused in that local area on the insulating interlayers 113 and 110 due to the fact that the test probe TP cannot be pressed against the bonding area 120_{B}. Thus, it is possible to considerably improve a freedom of the wiring layout design for the I/O buffer.

Also, the surface of the bonding area 120_{B} cannot be marked with scores. Accordingly, when the wire is bonded on the bonding area 120_{B}, it is possible to obtain a sufficient bonding strength therebetween.

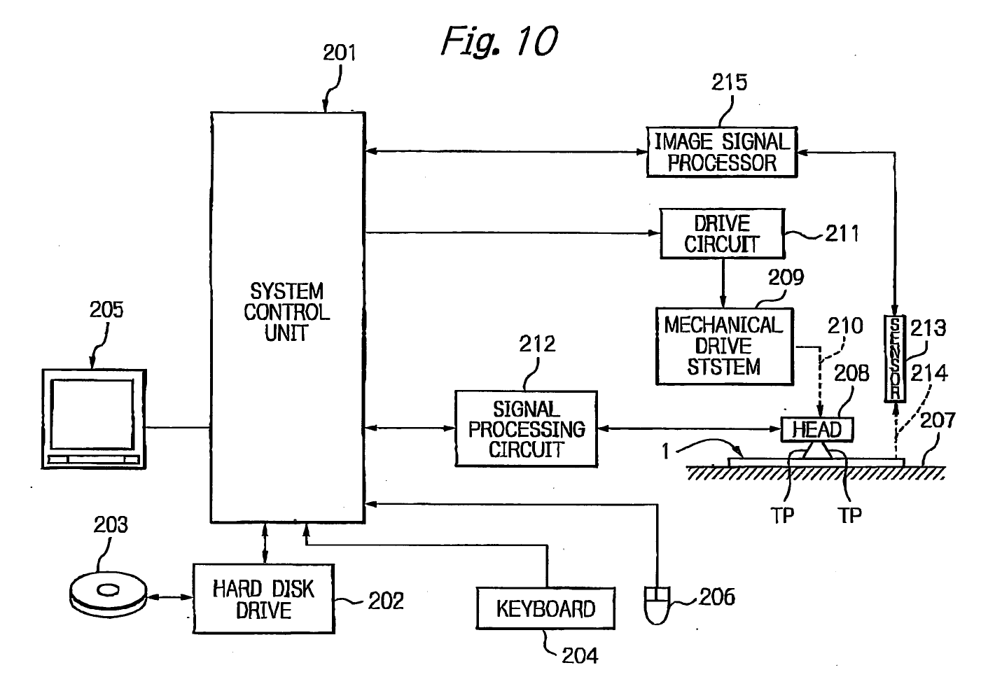

With reference to FIG. 10, a test system for testing the above-mentioned semiconductor wafer 1 is illustrated as a block diagram.

The test system, called an LSI tester, includes a system control unit 201 which contains a microcomputer having a central processing unit (CPU), a read-only memory (ROM) for storing programs and constants, a random-access memory (RAM) for storing temporary data, and an input/output (I/O) interface circuit.

The test system also includes a hard disk drive 202 for driving a hard disk 203 on which test programs, other programs, tables, various data and so on are stored. The system control unit 201 writes the various programs, tables and data on the hard disk 203 through the hard disk drive 202, 30 and also reads them from the hard disk 203 through the hard disk drive 201, if necessary.

The test system further includes a keyboard 204 for inputting various commands and data to the system control unit 201 though the I/O interface circuit thereof. The test system is provided with a display unit (CRT or LCD) 205 for displaying various command items, various information data and so on, and a mouse 206 for inputting a command to the system control unit 201 by clicking the mouse 206 on any one of the command items displayed on the display unit 205.

The test system additionally includes a test stage 207 on which the semiconductor wafer 1 is placed and positioned while the test is performed. Although not shown in FIG. 10, the test system includes an automatic wafer transferring/positioning system by which the semiconductor wafer 1 is transferred to and positioned at a predetermined position an the test stage 207. After the test is completed, the semiconductor wafer 1 is removed from the test stage 207 by the automatic wafer transferring/positioning system.

The test system further includes a movable test head 208 which is provided with a plurality of test probes TP to thereby test, at once time, the six semiconductor chip areas or devices Cᵢⱼ arranged in a 2×3 matrix manner. Namely, the test probes TP of the test head 208 are arranged so that, for example, the six semiconductor devices C₂₂, C₃₂, C₄₂, C₂₃, C₃₃ and C₄₃ can be tested at once time. Note that only two of the test probes TP are representatively and symbolically illustrated in FIG. 10.

The test head 208 is driven and moved by a mechanical drive system 209. Namely, the mechanical drive system 209 includes a drive mechanism to which the test head 208 is mechanically and operationally connected, and electric drive motors for driving the drive mechanism to thereby move the test 30 head 208 along the X-coordinate axis and the Y-coordinate axis (see: FIG. 5), which are defined with respect to the semiconductor wafer 1 positioned at the predetermined position on the test stage 207. Note, in FIG. 10, the mechanical and movable connection of the test head 208 to the drive mechanism of the mechanical drive system 209 is symbolically and conceptually represented by an arrow-headed broken line 210. The drive motors of the mechanical drive s system 209 are driven by a drive circuit 211 which is operated under control of the system control unit 64. Namely, the movement of the test head 208 is controlled by the system control unit 201 through the drive circuit 21l.

The test system is provided with a signal processing circuit 212 which is connected to the test head 208. The signal processing circuit 212 produces and outputs test signals to the test probes TP of the test head 208, and then receives response signals therefrom.

As shown in FIG. 10, the test system is also provided with an image sensor 213 for photographing an image of the semiconductor wafer 1, as symbolically and conceptually represented by an arrow-headed broken line 214, and the image sensor 213 may be constituted as a CCD (charge-couple device) image sensor. The CCD image sensor 213 is connected to an image signal processor 215 which is operated under control of the system control unit 201. The CCD image sensor 213 detects a frame of still image signals, and outputs the same to the image signal processor 215. The frame of still image signals is suitably processed in the image signal processor 215, and is then fed to the system control unit 201, and the image of the semiconductor wafer 1 is displayed on a screen of the display unit 205.

FIG. 11 shows a test routine which is executed in the system control unit 201. Note, the execution of the test routine is started by either operating a previously allocated function key on the keyboard 204 or double-clicking the mouse 206 on a test staring item displayed on the display unit 205.

At step 1101, it is determined whether a semiconductor wafer 1 has been positioned at the predetermined position on the test stage 207 by the aforesaid automatic wafer transferring/positioning system (not shown). When the positioning of the semiconductor wafer 1 is confirmed, the control proceeds to step 1102, in which six semiconductor chip areas or devices Cᵢⱼ, arranged in the 2×3 matrix manner, are photographed by the image sensor 213, and a frame of still image signals is detected from the CCD image sensor 213 through the image signal processor 215. Then, at step 1103, an image of the six semiconductor devices Cᵢⱼ is displayed on the screen of the display unit 205. Note, for example, the six semiconductor devices concerned may be represented by references C₂₂, C₃₂, C₄₂, C₂₃, C₃₃ and C₄₃.

At step 1104, the geometrical lines L_{YP} and L_{YB} are is generated on the screen of the display unit 205 based on the probe area definition mark elements M_{YP} and M_{YB}, and the geometrical lines L_{XP} and L_{XB} are generated on the screen of the display unit 205 based on the bonding area definition mark elements M_{XP} and M_{XB} (see: FIGS. 8 and 9). Namely, a probe area 120_{P}, an intermediate area 120_{I} and a bonding area 120_{B} are defined in each of the electrode pads PD.

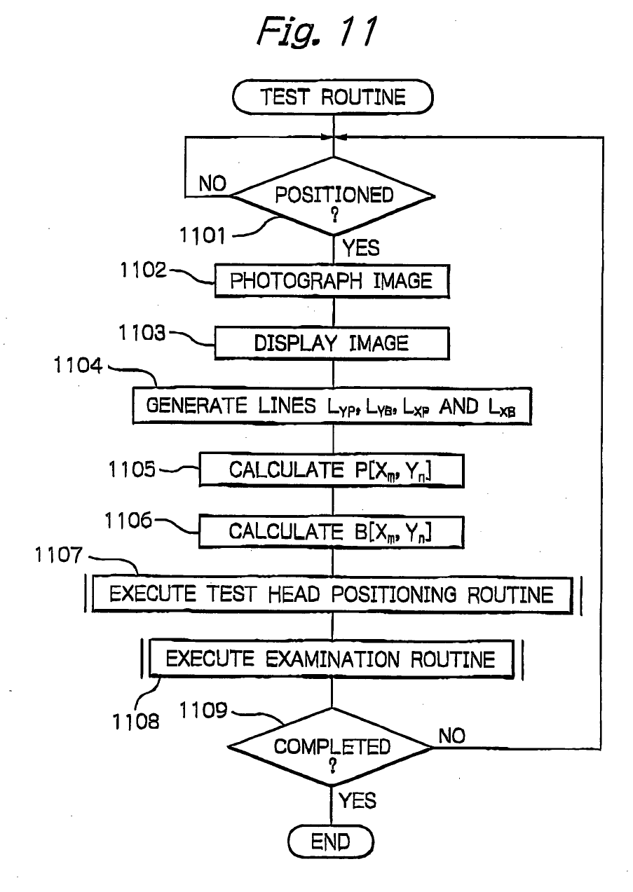

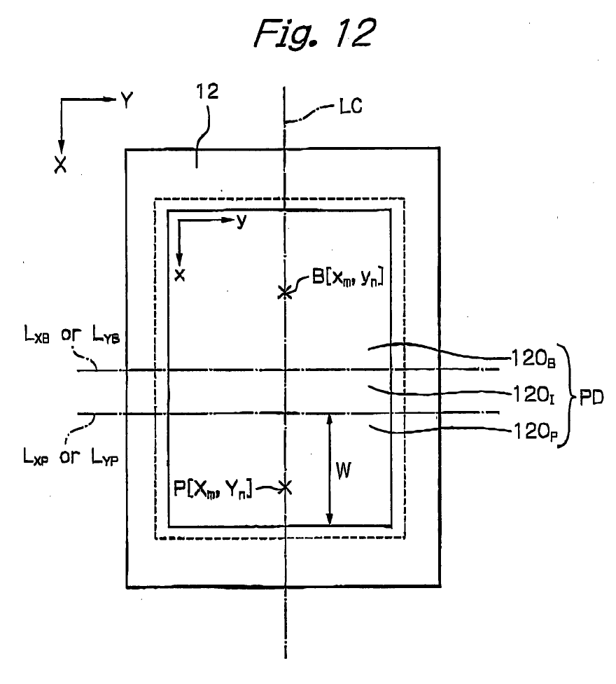

At step 1105, as representatively shown in FIG. 12, a probe contact point P [Xₘ, Yₙ], at which a test probe TP should be contacted with each of the probe areas 120_{P}, is calculated with respect to the X-Y coordinate system. For example, the probe contact point P[Xₘ, Yₙ] may be defined as a point which is sited on a longitudinal center line LC passing through the electrode pad PD, and which is located at a ⅓ of a width W of the probe area 120_{P} measured from a side edge of the electrode pad PD.

At step 1106, as representatively shown in FIG. 12, a bonding point B[xₘ, yₙ], at which a bonding wire should be bonded to each of the bonding areas 120_{B}, is calculated with respect to an x-y coordinate system defined to the electrode pad PD. The bonding point B[xₘ, yₙ] may be defined as a center on the bonding area 120_{B}. Also, the origin of the x-y coordinate system may be defined as a corner of the electrode pad PD, with the x-coordinate axis and y-coordinate axis of the x-y coordinate system being defined as the sides of the bonding area 120_{B} forming the aforesaid corner.

Note, after the execution of the test routine is completed, the bonding point B[xₘ, yₙ] is stored as bonding data on the hard disk 203 through the hard disk drive 202.

At step 1107, a test head positioning routine is executed as a subroutine. In particular, by executing the test head positioning routine, the test head 208 is moved to a position just above the six semiconductor devices Cᵢⱼ arranged in the 2×3 matrix manner, so that the plurality of test probes TP are registered with the respective probe contact points P[Xₘ, Yₙ]. Then, the test head 208 is moved down until the respective test probes TP are contacted with and pressed against the probe areas 120_{P} at the probe contact points P[Xₘ, Yₙ].

At step 1108, an examination routine is executed as a subroutine. In the examination routine, it is examined whether or not each of the six semiconductor devices Cᵢⱼ is properly operated. Namely, the signal processing circuit 212 outputs test signals to some of the test probes TP of the test head 206, and then receives response signals from other test probes TP of the test head 208. After the response signals are suitably processed in the signal processing circuit 212, these response signals are output to the system control unit 201, in which it is examined whether each of the semiconductor devices Cᵢⱼ is acceptable or unacceptable based on the response signals.

At step 1109, it is determined whether the test of all the semiconductor devices Cᵢⱼ is completed. When the test of all the semiconductor devices Cᵢⱼ is not completed, the control returns to step 1101. When the test of all the semiconductor devices Cᵢⱼ is completed, the test routine ends.

As stated above, when the test head positioning routine at step 1107 is executed, the respective test probes TP are contacted with and pressed against the probe areas 120_{P} at the probe contact points P[Xₘ, Yₙ].

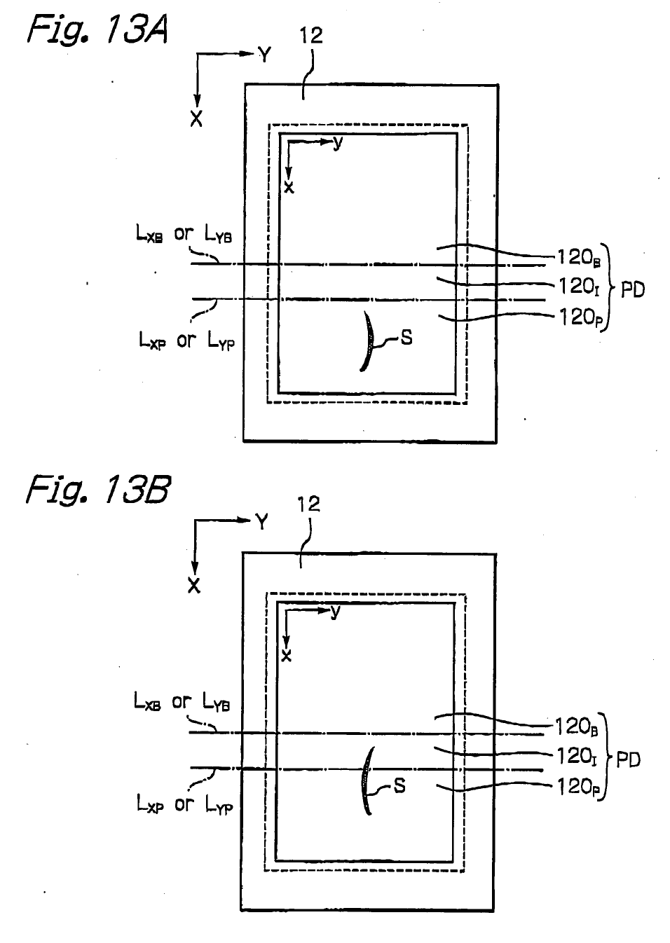

At the time, as shown in FIG. 13A, each of the probe areas 120_{P} is marked with score S by the test probe TP, and it is intended that the score S is confined in the probe area 120_{P}.

Nevertheless, as shown in FIG. 13B, there may be a case where the score S rarely and inevitably penetrates into the intermediate area 120_{I}. At worst, the bonding area 120_{I} may be accidentally marked with a score (S). In this case, cracks may be generated in a local area of the insulating interlayers 113 and 110 (see: FIG. 7), which is just beneath both the intermediate and bonding area 120_{I} and 120_{B}, by pressing the test probe TP against both the intermediate and bonding area 120_{I} and 120_{B}. The generated cracks may exerted a bad influence on the wiring pattern layer 112′ formed on the insulating interlayer 110. Namely, a current leakage may occur in the wiring pattern layer 112′ due to the existence of the cracks.

Accordingly, after the execution of the test routine of FIG. 11 is completed, it is necessary to prove whether or not the score S penetrates into both the intermediate area 120_{I} and the bonding area 120_{B},

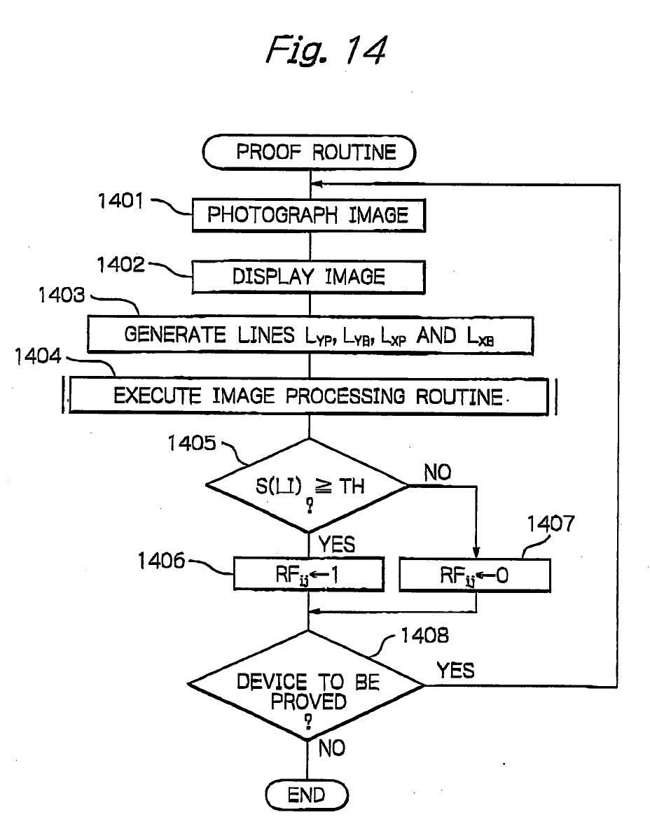

FIG. 14 shows a proof routine which is executed in the system control unit 201 after the execution of the test routine of FIG. 11 is completed. Note, the execution of the proof routine is also started by either operating a previously allocated function key on the keyboard 204 or double-clicking the mouse 206 on a proof staring item displayed on the display unit 205.

At step 1401, a semiconductor chip area or device Cᵢⱼ is photographed by the image sensor 213, and a frame of still image signals is detected, from the CCD image sensor 213, through the image signal processor 215. Then, at step 1402, an image of the semiconductor device Cᵢⱼ is displayed on the screen of the display unit 205.

At step 1403, the geometrical lines L_{XP} and L_{XB} are generated on the screen of the display unit 205 based on the probe area definition mark elements M_{YP} and M_{YB}, and the geometrical lines L_{YP} and L_{YB} are generated on the screen of the display unit 205 based on the bonding area definition mark elements M_{XP} and M_{XB} (see: FIGS. 13A and 13B). Namely, the probe area 120_{P}, intermediate area 120_{I} and bonding area 120_{B} are defined in each of the electrode pads PD of the semiconductor device Cᵢⱼ concerned.

At step 1404, an image processing routine is executed as a subroutine to thereby determine whether a score image S exists in both the intermediate area 120_{I} and the bonding area 120_{B}. In particular, in the execution of the image processing routine, the image signals, which are included in both the intermediate area 120_{I} and the bonding area 120_{B} of each of the electrode pads PD, are subjected to a labeling process so that a labeled image is produced in both the intermediate area 120_{I} and the bonding area 120_{B}. Namely, in both the intermediate area 120_{I} and the bonding area 120_{B}, an area, having a luminance value different from a background luminance value, is extracted as a labeled image LI.

At step 1405, it is determined whether a size or area value S(LI) of the labeled image LI is equal to or larger than a predetermined threshold value TH.

At step 1405, if S(LI)≧TH, the labeled image LI is regarded as a score S, and the control proceeds to step 1406, in which reject flag RFᵢⱼ, assigned to the semiconductor device Cᵢⱼ concerned, is made to “1”.

At step 1405, if S(LI)<TH, the labeled image LI is regarded as a noise, and the control proceeds to step 1407, in which the reject flag RFᵢⱼ, assigned to the semiconductor device Cᵢⱼ concerned, is made to “0”.

Note, after the execution of the proof routine is completed, the reject flag RFᵢⱼ is stored on the hard disk 203 through the hard disk drive 202.

In either event, at step 1408, it is determined whether the proof routine should be repeated, i.e., whether a semiconductor device Cᵢⱼ remains to be proved. When such a semiconductor device Cᵢⱼ remains, the control returns to step 1401. When there is no semiconductor device Cᵢⱼ to be proved, the routine ends.

The proved semiconductor wafer 1 may be further tested and proved by another LSI tester, if necessary. In this case, the probe area definition mark elements M_{YP} and M_{YB} and the bonding area definition mark elements M_{XP} and M_{YB} are utilized in substantially the same manner as mentioned above.

Thereafter, the semiconductor wafer 1 is subjected to a dicing process by a dicing apparatus, and the semiconductor wafer 1 is cut along the grid-like scribe line areas 2X₁ to 2X₅ and 2Y₁ to 2Y₅, so that the semiconductor chip devices are separated from each other. In this case, the semiconductor device Cᵢⱼ, to which “1” is assigned as the reject flag RFᵢⱼ, is put into the discard as a reject product, and the semiconductor device Cᵢⱼ, to which “0” is assigned as the reject flag RFᵢⱼ, is used for forming a semiconductors package.

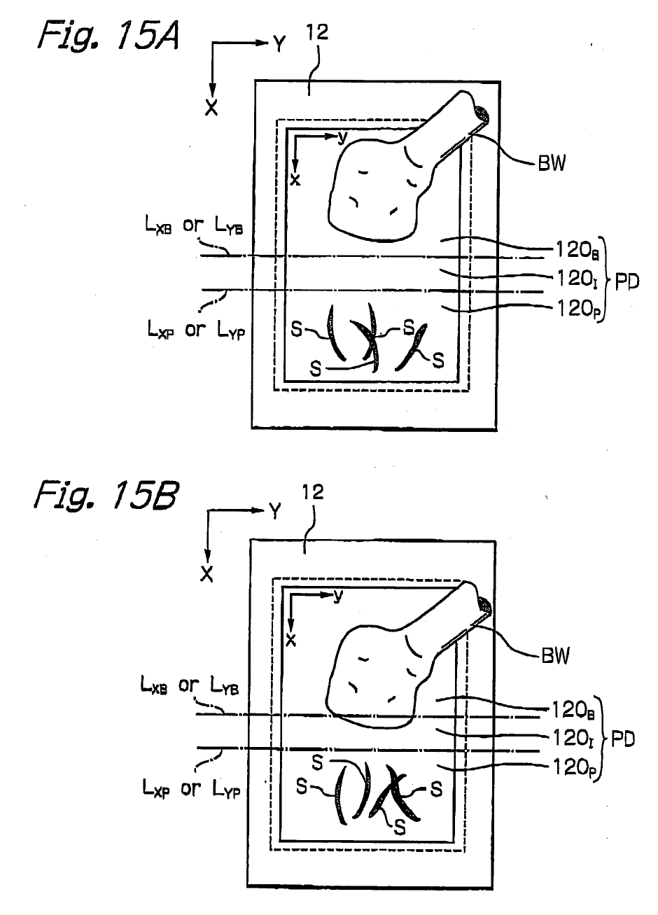

As shown in FIG. 15A, in the formation of the semiconductor package, a bonding wire BW is bonded on the bonding area 120_{B} of the electrode pad PD at the bonding point B[xₘ, yₙ] (see: FIG. 12) by using, for example, an ultrasonic-pressure type wire-bonding apparatus. As the bonding area 120_{B} cannot be marked with a score, it is possible to obtain a sufficient bonding strength between the bonding area 120_{B} and the bonding wire BW. Of course, in this case, the positions of all the bonding points B[xₘ, yₙ] are previously loaded as bonding data in the wire-bonding apparatus.

As shown in FIG. 15B, the intermediate area 120_{I} may be utilized as a part of the bonding area 120_{B}. Namely, an area, which is obtained by combining both the intermediate area 120_{I} and the bonding area 120_{B}, is defined as a bonding is area, and a bonding point B[xₘ, yₙ] is defined as a center of the combined area. In this case, the lines L_{XB} and L_{YB} are made redundant, and thus the bonding area definition mark elements M_{XB} and M_{YB} can be omitted.

### Second Embodiment

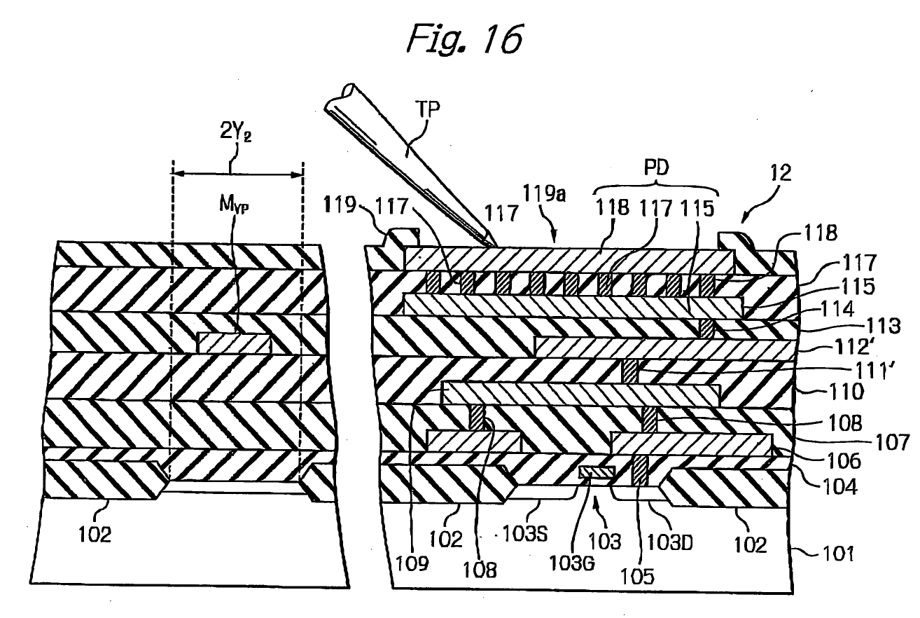

In FIG. 16, which corresponds to FIG. 7, a second embodiment of the semiconductor device according to the present invention is illustrated. The second embodiment is substantially identical to the above-mentioned first embodiment except that the probe area definition mark elements M_{XP} and M_{YP} and the bonding area definition mark elements M_{YB} and M_{YB} are defined as metal or aluminum layers.

Namely, as representatively shown in FIG. 16, the probe area definition mark element M_{YP} is defined as the aluminum layer formed on the insulating interlayer 110, and the formation of the probe area definition mark element M_{YP} is simultaneously carried out when the wiring pattern layer 112′ is formed on the insulating interlayer 110. The same is true for the other mark elements M_{YP}, M_{YB}, M_{XP} and M_{XB}.

In the second embodiment, although the insulating interlayer 110 is utilized for the formation of the mark elements M_{YP}, M_{YB}, M_{XP} and M_{XB}, it is possible to form these mark elements M_{YP}, M_{YB}, M_{XP} and M_{XB} on any one of the insulating interlayers 104, 107, 113 and 117.

### Third Embodiment

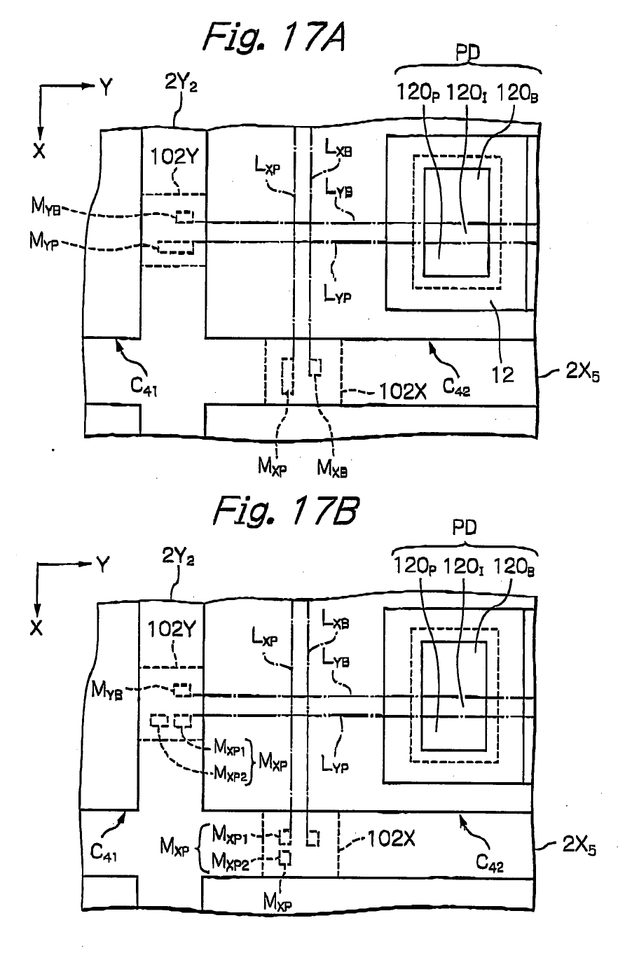

In FIG. 17A, in which a part of the semiconductor chip area C₄₂ of FIG. 5 is shown in an enlarged scale, a third embodiment of the semiconductor device according to the present invention is illustrated.

In the third embodiment, the probe area definition mark element M_{YP} has a larger size than that of the bonding area definition mark element M_{YB}, so that the mark elements M_{YP} and M_{YB} can be easily distinguished from each other. Similarly, the probe area definition mark element M_{XP} has a larger size than that of the bonding area definition mark element M_{XB,}so that the mark elements M_{XP} and M_{XB} can be easily distinguished from each other.

In FIG. 17B which shows a modification of the third embodiment of FIG. 17A, the probe area definition mark element M_{YP} is composed of two-piece sections M_{YP1} and M_{YP2}, so that the mark element M_{YP} (M_{YP1} and M_{YP2}) can be easily distinguished from the bonding area definition mark element M_{YB}. Similarly, the probe area definition mark element M_{XP} is composed of two-piece sections M_{XP1} and M_{XP2}, so that the mark element M_{XP} (M_{XP1} and M_{XP2}) can be easily distinguished from the bonding area definition mark element M_{XB}.

Notes in the third embodiment, the two-piece sections M_{XP1} and M_{XP2}, the two-piece sections M_{YP1} and M_{YP2} and the bonding area mark elements M_{XB} and M_{YB} may be defined as aluminum layers formed on any one of the insulating interlayers 104, 107, 110, 113 and 117.

### Fourth Embodiment

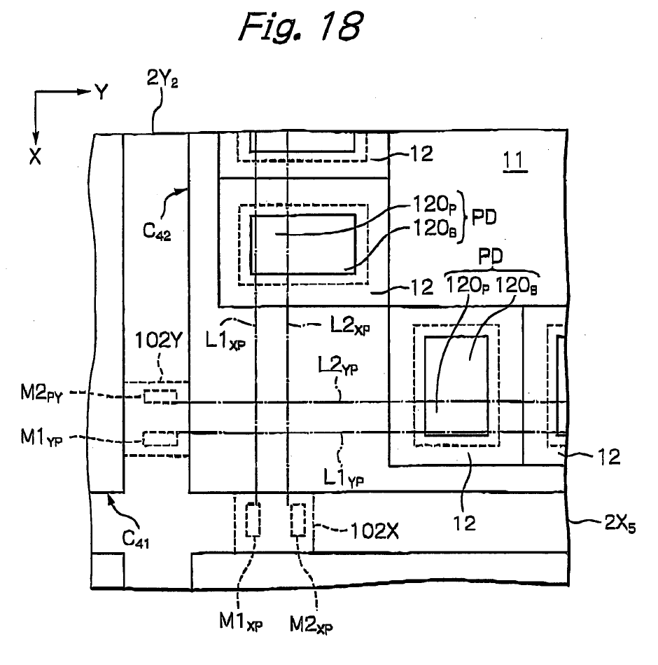

In FIG. 18, in which a part of the semiconductor chip area C₄₂ of FIG. 5 is shown in an enlarged scale, a fourth embodiment of the semiconductor device according to the present invention is illustrated.

In the fourth embodiment, a pair of rectangular openings are perforated in each of the sections 102Y so that a pair of probe area definition mark elements M1_{YP} and M2_{YP} are defined as respective impurity-diffusion regions. The probe area definition mark elements M1_{YP} and M2_{YP} are used to generate a pair of line L1_{XP} and L2_{XP} so that a probe area 120_{P} is defined between the line L1_{YP} and L2_{YP} in each of the electrode pads PD arranged along the Y-coordinate axis, with a bonding area 120_{B} being defined with the line L2_{YP} in each of the electrode pads PD concerned.

Similarly, a pair of rectangular openings are perforated in each of the sections 102X so that a pair of probe area definition mark elements M1_{XP} and M2_{XP} are defined as respective impurity-diffusion regions. The probe area definition mark elements M1_{XP} and M2_{XP} are used to generate a pair of line L1_{XP} and L2_{XP} so that a probe area 120_{P} is defined between the line L1_{XP} and L2_{XP} in each of the electrode pads PD arranged along the Y-coordinate axis, with a bonding area 120_{P} being defined with the line L2_{XP} in each of the electrode pads PD concerned.

In the fourth embodiment, each of the probe areas 120_{P}, which are arranged along the Y-coordinate axis, is further limited and narrowed by the line L1_{YP} in the direction of the X-coordinate axis. Also, each of the probe areas 120_{P}, which are arranged along the X-coordinate axis, is further limited and narrowed by the line L1_{XP} in the direction of X-coordinate axis. Namely, in the fourth embodiment, each of the probe areas 120_{P} has a smaller area in comparison with the cases of the above-mentioned first, second and third embodiments. Thus, it is possible to further improve the freedom of the wiring layout design for the I/O buffer.

Note, in the fourth embodiment, the probe area definition mark elements M1_{XP} and M2_{XP} and M1_{YP} and M2_{YP} may be defined as aluminum layers formed on any one of the insulating interlayers 104, 107, 110, 113 and 117.

### Fifth Embodiment

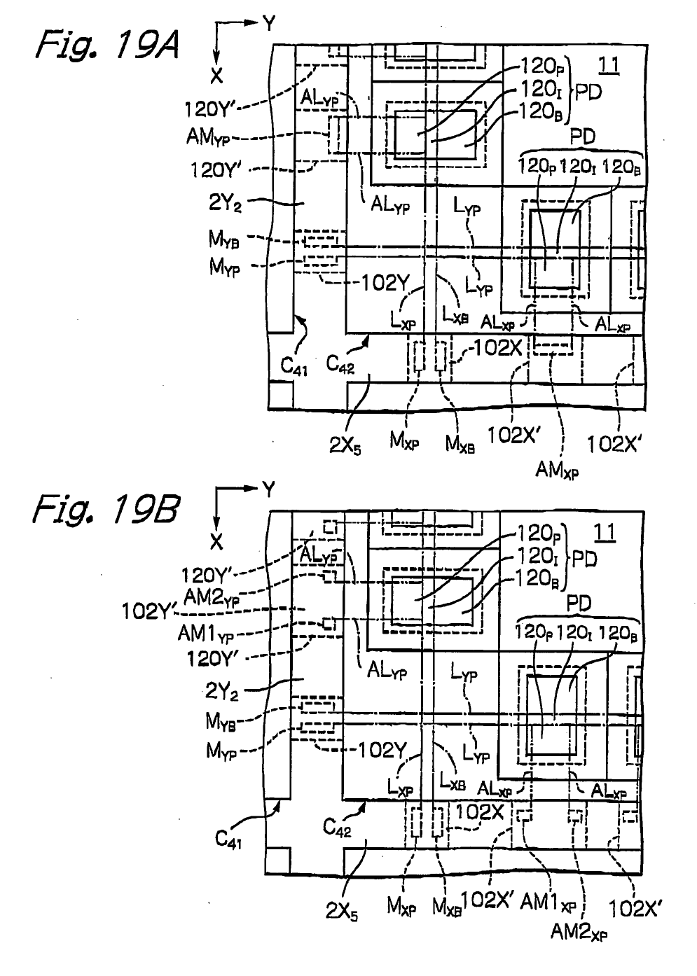

In FIG. 19A, in which a part of the semiconductor chip area C₄₂ of FIG. 5 is shown in an enlarged scale, a fifth embodiment of the semiconductor device according to the present invention is illustrated.

In the fifth embodiment, the consecutive two element-isolation layers 102 (see: FIG. 7), arranged along the X-coordinate axis, are connected to each other by additional sections 102X′ which are provided beside the respective I/O area sections 12 arranged along the scribe line area 2X₅. An elongated opening is perforated in each of the additional sections 102X′ so that an additional probe area definition mark element AM_{XP} is defined as an impurity-diffusion region. The additional probe area definition mark element AM_{XP} is used to generate a pair of additional lines AL_{XP} for further limiting and narrowing the probe area 120_{P} in the direction of the Y-coordinate axis.

Similarly, the consecutive two element-isolation layers 102 (see: FIG. 7), arranged along the Y-coordinate axis, are connected to each other by additional sections 102Y′ which are provided beside the respective I/O area sections 12 arranged along the scribe line area 2Y₂. An elongated opening is perforated in each of the additional sections 102Y′ so that an additional probe area definition mark element AM_{YP} is defined as an impurity-diffusion region. The additional probe area definition mark element AM_{YP} is used to generate a pair of additional lines AL_{YP} for further limiting and s narrowing the probe area 120_{P} in the direction of the X-coordinate axis.

In short, each of the probe areas 120_{P}, which are arranged along the Y-coordinate axis, is further limited and narrowed by the pair of additional lines AL_{XP} in the direction of the Y-coordinate axis, and each of the probe areas 120_{P}, which are arranged along the X-coordinate axis, is further limited and narrowed by the pair of additional lines AL_{YP} in the direction of the X-coordinate axis. As a result, it is possible to further improve a freedom of the wiring layout design for the I/O buffer.

Note, in the fifth embodiment, the probe area definition mark elements M_{YP} and M_{XP}, the additional probe area definition mark elements. AM_{YP} and AM_{XP}, and the bonding area definition mark elements M_{YB} and M_{XB} may be defined as aluminum layers formed on any one of the insulating interlayers 104, 107, 110, 113 and 117.

In FIG. 19B, which shows a modification of the fifth embodiment, a pair of additional probe area definition mark elements AM1_{XP} and AM2_{XP} are substituted for the probe area definition mark element AM_{XP}, to thereby generate the additional lines AL_{XP}, and a pair of additional probe area definition mark elements AM1_{YP} and AM2_{YP} are substituted for the probe area definition mark element AM_{YP}, to thereby generate the additional lines AL_{YP}. Namely, except for this regard, the embodiments of FIGS. 19A and 19B are identical to each other.

### Sixth Embodiment

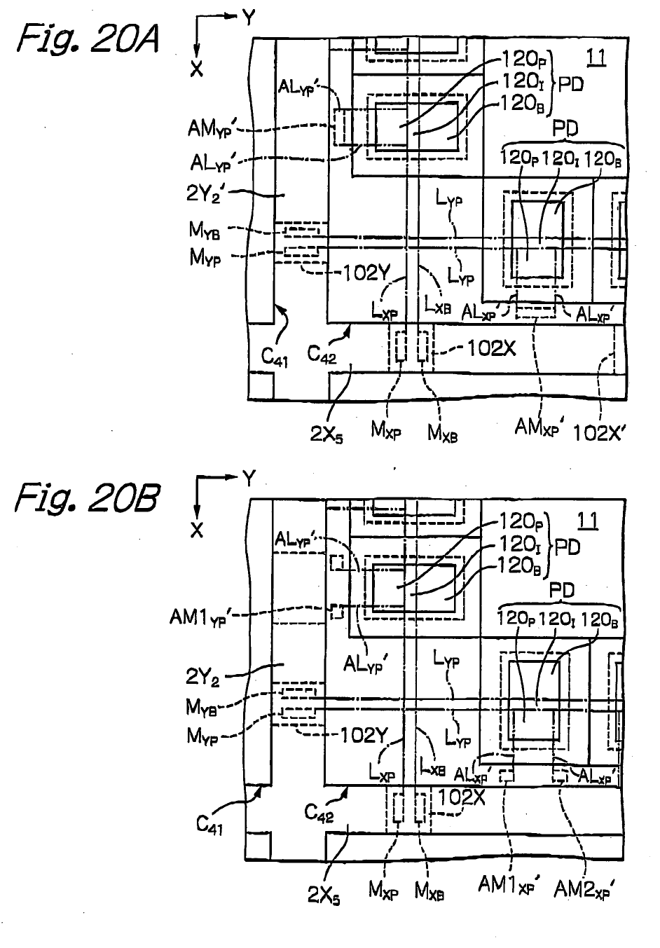

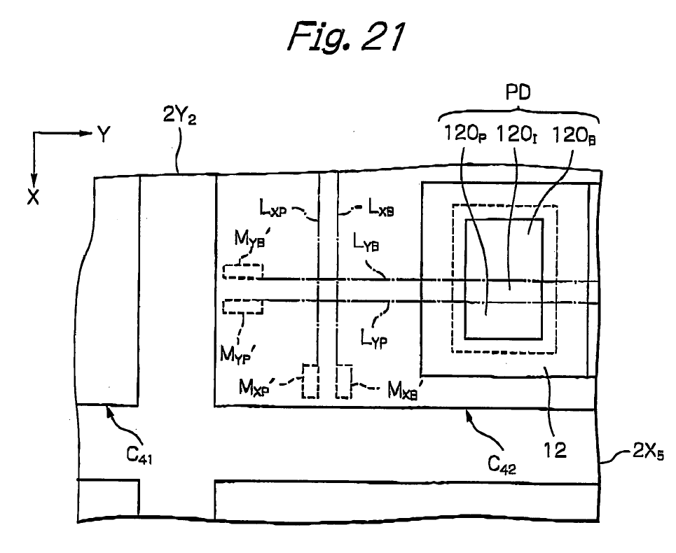

In FIG. 20A, in which a part of the semiconductor chip area C₄₂ of FIG. 5 is shown in an enlarged scale, a sixth embodiment of the semiconductor device according to the present invention is illustrated.

In the sixth embodiment, an elongated additional probe area definition mark element AM_{XP′} is formed in a peripheral margin area of the semiconductor device C₄₂ between the scribe line area 2X₅ and the I/O area sections 12 arranged therealong. Namely, an elongated opening is perforated in lo the element-isolation layer 102 (see: FIG. 7) in the aforesaid margin area beside the corresponding the I/O area section 12, so that the elongated additional probe area definition mark element AM_{XP′} is defined as an impurity-diffusion region.

The additional probe area definition mark element AM_{XP′} is used to generate a pair of additional lines AL_{XP′} for further limiting and narrowing the probe area 120_{P} in the direction of the Y-coordinate axis.

Similarly, an elongated additional probe area definition mark element AM_{YP′} is formed in a peripheral margin area of the semiconductor device C₄₂ between the scribe line area 2Y₂ and the I/O area sections 12 arranged therealong. Namely, an elongated opening is perforated in the element-isolation layer 102 (see: FIG. 7) in the aforesaid margin area beside the corresponding the I/O area section 12, so that the elongated additional probe area definition mark element AM_{YP′} is defined as an impurity-diffusion region.

The additional probe area definition mark element AM_{YP′} is used to generate a pair of additional lines AL_{YP′} for further limiting and narrowing the probe area 120_{P} in the direction of the X-coordinate axis.

In short, similar to the above-mentioned fifth embodiment of FIG. 19A, each of the probe areas 120_{P}, which are arranged along the Y-coordinate axis, is further limited and narrowed by the pair of additional lines AL_{XP′} in the direction of the Y-coordinate axis, and each of the probe areas 120_{P}, which are arranged along the X-coordinate axis, is further limited and narrowed by the pair of additional lines AL_{YP′} in the direction of the X-coordinate axis. As a result, it is possible to further improve a freedom of the wiring layout design for the I/O buffer.

Note, in the sixth embodiment, the probe area definition mark elements M_{YP} and M_{XP}, the additional probe area definition mark elements AM_{YP′} and AM_{XP′}, and the bonding area definition mark elements M_{YB} and M2_{XB} may be defined as aluminum layers formed on any one of the insulating interlayers 104, 107, 110, 113 and 117.

In FIG. 20B which shows a modification of the sixth embodiment, a pair of additional probe area definition mark elements AM1_{XP′}, and AM2_{XP′} are substituted for the probe area definition mark element AM_{XP′}, to thereby generate the additional lines AL_{XP′}, and a pair of additional probe area definition mark elements AM1_{YP′}, and AM2_{YP′} are substituted for the probe area definition mark element AM_{YP′} to thereby generate the additional lines AL_{YP′}. Namely, except for this regard, the embodiments of FIGS. 20A and 20B are identical to each other.

### Seventh Embodiment

In FIG. 21, in which a part of the semiconductor chip area C₄₂ of FIG. 5 is shown in an enlarged scale, a seventh embodiment of the semiconductor device according to the present invention is illustrated.

In the seventh embodiment, a probe area definition mark element M_{XP′} and a bonding area definition mark element M_{XB′} are formed in a corner margin area of the semiconductor device C₄₂. Namely, two openings are perforated in the element-isolation layer 102 (see: FIG. 7) in the aforesaid corner margin area, so that each of the mark elements M_{XP′} and M_{XB′} are defined as an impurity-diffusion region. The respective mark element M_{XP′} and M_{XB′} are used to generate the lines L_{XP} and L_{XB} in the direction of the X-coordinate axis.

Similarly, a probe area definition mark element M_{YP′} and a bonding area definition mark element M_{YB′} are formed in the corner margin area of the semiconductor device C₄₂. Namely, two openings are perforated in the element-isolation layer 102 (see: FIG. 7) in the aforesaid corner margin area, so that each of the mark elements M_{YP′} and M_{YB′} are defined as an impurity-diffusion region. The respective mark element M_{YP′} and M_{YB′} are used to generate the lines L_{YP} and L_{YB} in the direction of the Y-coordinate axis.

Note, in the seventh embodiment, the probe area definition mark elements M_{YP′} and M_{XP′} and the bonding area definition mark elements M_{YB′} and M2_{XB}, may be defined as aluminum layers formed on any one of the insulating interlayers 104, 107, 110, 113 and 117.

Finally, it will be understood by those skilled in the art that the foregoing description is of preferred embodiments of the devices, and that various changes and modifications may be made to the present invention without departing from the spirit and scope thereof.

1. A semiconductor device comprising;
a semiconductor substrate;
a multi-layered wiring structure formed on said semiconductor substrate;
an electrode pad formed on said multi-layered wiring structure; and
a probe area definition mark element that defines a probe area in said electrode pad, with which a test probe should be contacted.

2. The semiconductor device as set forth in claim 1, wherein said probe area definition mark element is provided at a location spaced away from said electrode pad.

3. The semiconductor device as set forth in claim 2, wherein said electrode pad comprises a metal layer formed on an uppermost insulating interlayer of said multi-layered wiring structure, said uppermost insulating interlayer having an insulating layer formed thereon to cover said metal layer, said insulating layer having an opening perforated therein so that a part of said metal layer is exposed to an exterior as said electrode pad, said location being spaced away from a peripheral edge of said opening.

4. The semiconductor device as set forth in claim 1, wherein said probe area definition mark element is located in a scribe line area defined on said semiconductor substrate.

5. The semiconductor device as set forth in claim 1, wherein said probe area definition mark element is located at a margin area of a semiconductor chip area which is defined on said semiconductor substrate, said semiconductor device being formed in said semiconductor chip area.

6. The semiconductor device as set forth in claim 1, wherein said probe area definition mark element is defined as an impurity diffusion region formed in said semiconductor substrate.

7. The semiconductor device as set forth in claim 1, wherein said probe area definition mark element is defined as a metal layer formed on an insulating interlayer of said multi-layered wiring structure.

8. The semiconductor device as set forth in claim 1, further comprising a bonding area definition mark element that collaborates with said bonding area definition mark element so as to define a bonding area in said electrode pad, on which a bonding wire be bonded.

9. The semiconductor device as set forth in claim 1, further comprising a wiring pattern layer formed on an insulating interlayer of said multi-layered wiring structure, which is beneath said electrode pad, said wiring pattern layer being excluded from a local area on said insulating interlayer, which is beneath the probe area of said electrode pad.

10. A semiconductor device comprising:
a semiconductor substrate;
a multi-layered wiring structure formed on said semiconductor substrate;
a plurality of electrode pads formed on said multi-layered wiring structure so as to be aligned with each other; and
a first probe area definition mark element and a second probe area definition mark element which are arranged so that said electrode pads are aligned and intervened therebetween to define respective probe areas in said electrode pads, with which a test probe should be contacted.

11. The semiconductor device as set forth in claim 10, wherein said first and second probe area definition mark elements are provided at respective locations spaced from the outermost electrode pads of the alignment of said electrode pads.

12. The semiconductor device as set forth in claim 11, wherein each of said electrode pads comprises a metal layer formed on an uppermost insulating interlayer of said multi-layered wiring structure, said uppermost insulating interlayer having an insulating layer formed thereon to cover said metal layer, said insulating layer having an opening perforated therein so that a part of said metal layer is exposed to an exterior as said electrode pad, said locations being spaced from respective peripheral edges of the openings of said outermost electrode pads.

13. The semiconductor device as set forth in claim 10, wherein said first and second probe area definition mark elements are located in respective scribe line areas which are defined on said semiconductor substrate.

14. The semiconductor device as set forth in claim 10, wherein each of said first and second probe area definition mark elements is located at a margin areas of a semiconductor chip area which is defined on said semiconductor substrate, the semiconductor device being formed in said semiconductor chip area.

15. The semiconductor device as set forth in claim 10, wherein each of said first and second probe area definition mark elements is defined as an impurity diffusion region formed in said semiconductor substrate.

16. The semiconductor device as set forth in claim 10, wherein each of said first and second probe area definition mark elements is defined as a metal layer formed on an Insulating interlayer of said multi-layered wiring structure.

17. The semiconductor device as set forth in claim 10, further comprising a first bonding area definition mark element and a second bonding area definition mark element which collaborates with said respective first and second probe area definition mark elements so as to define respective bonding areas, in said electrode pads, on which bonding wires be bonded.

18. The semiconductor device as set forth in claim 10, further comprising a wiring pattern layer formed on an insulating inter layer of said multi-layered wiring structure, which is beneath said electrode pad, said wiring pattern layer being excluded from local areas on said insulating interlayer, which are beneath the probe areas of said electrode pads.

19. A proof test system that proves whether a test probe is properly contacted with a probe area defined in an electrode pad on a semiconductor device featuring a probe area definition mark element, which system comprises:
an image sensor that photographs said electrode pad with together said probe area definition mark element;
a line generator system that generates a geometrical line based on the photographed image of said probe area definition mark element, to thereby define the probe area in said electrode pad, a remaining area of said electrode pad being defined as a bonding area on which a bonding wire should be bonded;
an image processing system that processes image data representing the bonding area of said electrode pad; and
a determination system that determines whether or not said bonding area is marked with a score by the test probe based on the image data processed by said image processing system.

20. The proof test system as set forth in claim 19, further comprising a data storage system that stores reject data, indicating that the semiconductor device concerned should be rejected, when the marking of said bonding area with a score is confirmed by said determination system.

21. The proof test system as set forth in claim 19, further comprising a display system that displays the image photographed by said image sensor and the geometrical line generated by said line generator system.
